(19) United States
(12) Patent Application Publication
(10) Pub. No.: US 2025/0203787 A1
(43) Pub. Date: Jun. 19, 2025

(54) ELECTRONIC DEVICE

(71) Applicant: DENSO CORPORATION, Kariya-City (JP)

(72) Inventors: KENTA YOSHIDOMI, Kariya-City (JP); TASUKU MURASE, Kariya-City (JP)

(21) Appl. No.: 18/910,791

(22) Filed: Oct. 9, 2024

(30) Foreign Application Priority Data
Dec. 19, 2023 (JP) 2023-214010

(51) Int. Cl. H05K 5/00; H05K 5/02; H05K 5/03

(52) U.S. Cl. CPC H05K 5/0052; H05K 5/0247; H05K 5/03

(57) ABSTRACT

An electronic device includes a circuit board having a connector and a case that houses the circuit board. The case includes a cover having an opening in which the connector is disposed, and a housing portion which, together with the cover, form an accommodation space for the circuit board. The cover has a first cover portion made of a soft material and having a first opening, and a second cover portion made of a hard material and having a second opening that is in contact with the first cover portion and has a larger opening area than the first opening. A portion that forms the first opening is provided in an annular shape along an outer periphery of the connector, and has at least a portion of a protruding part that protrudes outside the accommodation space.

### CROSS-REFERENCE TO RELATED APPLICATIONS

This application is based on Japanese Application No. 2023-214010 filed on Dec. 19, 2023, the disclosure of which is incorporated herein by reference.

### TECHNICAL FIELD

The present disclosure relates to an electronic device.

### BACKGROUND ART

An electronic device has a connector and a housing.

### SUMMARY

One disclosed object is to provide an electronic device with improved effect of preventing intrusion of foreign matter.

An electronic device disclosed herein is an electronic device including a circuit board having an external connection connector and a case for accommodating the circuit board.

The case includes a cover provided with an opening in which the external connection connector is disposed, and a housing portion which, together with the cover, forms an accommodation space for the circuit board.

The cover has a first cover portion made of a soft material and provided with a first opening that is a part of the opening, and a second cover portion made of a hard material and in contact with the first cover portion and provided with a second opening that is a part of the opening and has a larger opening area than the first opening.

A portion forming the first opening is provided in an annular shape along an outer periphery of the external connection connector, and has at least a protruding part that protrudes outside the accommodation space.

In this manner, the electronic device has a configuration in which the portion forming the first opening is provided in an annular shape along the outer periphery of the external connection connector. The portion that forms the first opening has at least a protruding part that protrudes outside the accommodation space.

### BRIEF DESCRIPTION OF DRAWINGS

FIG. 1 is a perspective view illustrating a schematic configuration of an electronic device according to a first embodiment;

FIG. 2 is a cross-sectional view taken along a line II-II of FIG. 1;

FIG. 3 is an outer plan view seen from a direction of an arrow III in FIG. 1;

FIG. 4 is an inner plan view showing a schematic configuration of a front cover;

FIG. 5 is a cross-sectional view taken along a line V-V in FIG. 3;

FIG. 6 is a cross-sectional view showing a schematic configuration of an electronic device according to a second embodiment;

FIG. 7 is a cross-sectional view showing a schematic configuration of an electronic device according to a third embodiment;

FIG. 8 is a cross-sectional view showing a schematic configuration of a front cover of a first modified example; and

FIG. 9 is a cross-sectional view showing a schematic configuration of a front cover of a second modified example.

### DETAILED DESCRIPTION

In an assumable example, an electronic device has a connector and a housing. In the electronic device, a dust cover is provided between a connector and a connector insertion port in order to prevent dust and other particles from entering the housing through a gap between the connector insertion port of the housing and an outer periphery of the connector. The dust cover is made of nonwoven fabric or an elastic material such as rubber or sponge.

The electronic device described above is expected to be effective in preventing foreign matter such as dust or dirt from entering the housing from the outside. However, in the electronic device, depending on the load applied to the dust cover by a foreign matter, there is a risk that the dust cover may be turned over, allowing the foreign matter to enter the housing. From the viewpoint described above or from other unmentioned viewpoints, there may be a demand for further improvement to the electronic device.

One disclosed object is to provide an electronic device with improved effect of preventing intrusion of foreign matter.

An electronic device disclosed herein is an electronic device including a circuit board having an external connection connector and a case for accommodating the circuit board.

The case includes a cover provided with an opening in which the external connection connector is disposed, and a housing portion which, together with the cover, forms an accommodation space for the circuit board.

The cover has a first cover portion made of a soft material and provided with a first opening that is a part of the opening, and a second cover portion made of a hard material and in contact with the first cover portion and provided with a second opening that is a part of the opening and has a larger opening area than the first opening.

A portion forming the first opening is provided in an annular shape along an outer periphery of the external connection connector, and has at least a protruding part that protrudes outside the accommodation space.

In this manner, the electronic device has a configuration in which the portion forming the first opening is provided in an annular shape along the outer periphery of the external connection connector. The portion that forms the first opening has at least a protruding part that protrudes outside the accommodation space. Therefore, the electronic device can prevent the protruding part from being peeled off even if a foreign matter attempts to enter the accommodation space. Thus, the electronic device can improve the effectiveness of inhibiting foreign matter from entering the accommodation space.

The disclosed aspects in this specification adopt different technical solutions from each other in order to achieve their respective objectives. Reference numerals in parentheses described in claims and this section exemplarily show corresponding relationships with parts of embodiments to be described later and are not intended to limit technical scopes. The objects, features, and advantages disclosed in this specification will become apparent by referring to following detailed descriptions and accompanying drawings.

As follows, multiple embodiments for implementing the present disclosure will be described with reference to the drawings. In each embodiment, portions corresponding to those described in the preceding embodiment are denoted by the same reference numerals, and redundant descriptions will be omitted in some cases. In each embodiment, in a case where only a part of the configuration is described, the other part of the configuration may be applied with reference to the other embodiment described above.

### First Embodiment

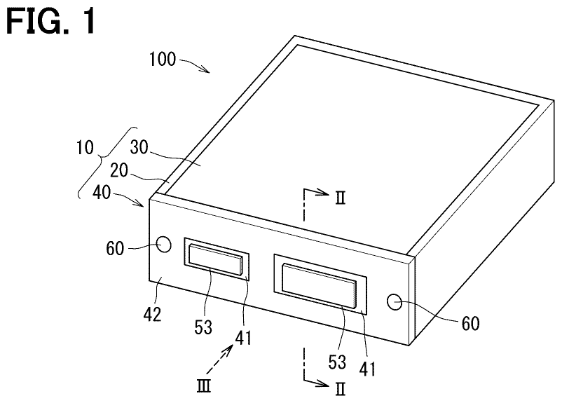

An electronic device 100 according to a first embodiment will be described with reference to FIG. 1 to FIG. 5. The electronic device 100 is configured to be mountable on a mobile object, for example. Examples of mobile objects include vehicles such as electric cars, hybrid cars, and fuel cell cars, flying objects such as electric vertical take-off and landing aircraft and drones, ships, construction machinery, and agricultural machinery.

In the present embodiment, as an example, the electronic device 100 is applied to an anti-theft device for a vehicle. The anti-theft device includes an immobilizer device and a locking device. Therefore, the electronic device 100 needs to comply with, for example, the United Nations Regulation (UNR 116) relating to anti-theft devices. Also, in order to comply with the regulations, IP40 requirements must be met. The IP40 requirement is a requirement to protect the case from solid objects having a diameter of 1.0 mm (φ1) or more. The IP40 requirement requires a structure in which a test rod (φ+0.05/0) cannot be inserted into the case even if a load of 1±0.1 N is applied.

### <Overall Configuration and Circuit Board>

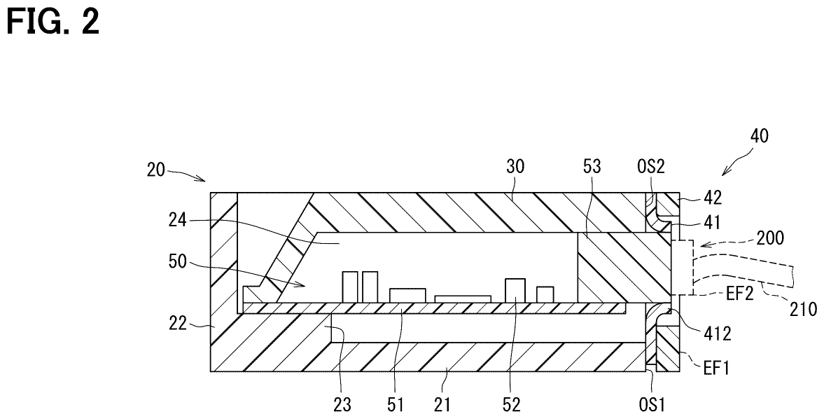

As shown in FIGS. 1 and 2, the electronic device 100 includes a circuit board 50 and a case 10 that houses the circuit board 50. The circuit board 50 includes a wiring board 51 on which a plurality of circuit components 52 and a connector 53 are mounted. The wiring board 51 is an electrically insulating substrate on which conductive wiring is formed. The wiring board 51 is fixed to the case 10 via bolts or the like.

The circuit components 52 and the connector 53 are mounted on the wiring board 51 and are electrically connected to the wiring. The connector 53 serves to electrically connect the electronic device 100 to an in-vehicle device provided outside the electronic device 100. The connector 53 includes a terminal electrically connected to the wiring of the wiring board 51, and a connector case that encloses the terminal.

In the present embodiment, as an example, the circuit components 52 and the connector 53 are mounted on a front surface side of the wiring board 51. However, the present disclosure is not only limited to the above example. The connector 53 may be mounted on a back surface of the wiring board 51. Furthermore, the circuit components 52 may be mounted on both the front and back surfaces of the wiring board 51 or only on the back surface of the wiring board 51. The front surface is the surface on a lid member 30 side. On the other hand, the back surface is the surface opposite to the front surface. The back surface is the surface that faces a bottom wall 21 of a base 20, which will be described later.

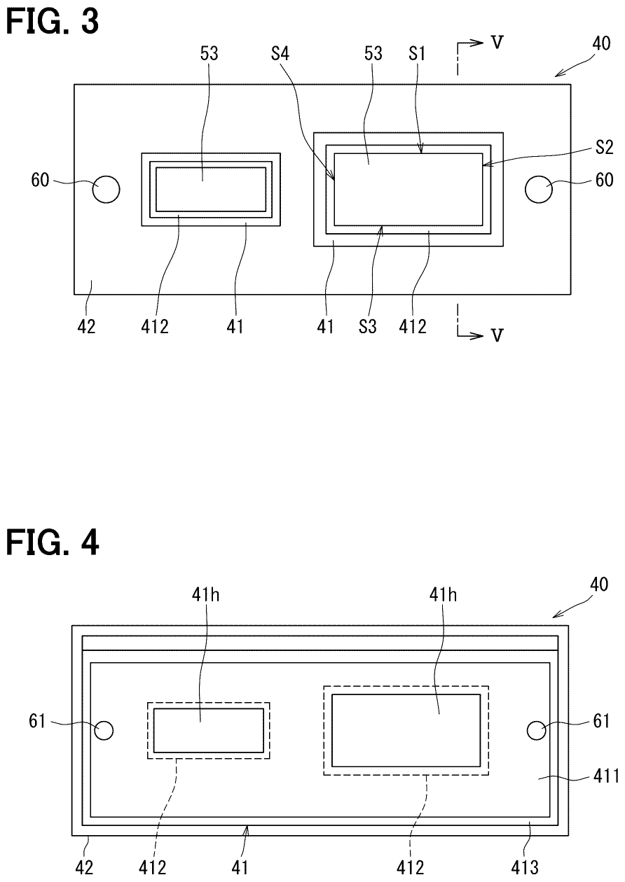

As shown in FIGS. 2 and 3, the connector 53 has, for example, four side surfaces S1 to S4 that form the outer periphery. The side surfaces S1 to S4 are the outer surfaces of the connector case. However, the side surface of the connector 53 may be circular (curved).

The connector 53 is configured so that a vehicle-side connector 200 can be attached thereto. Similar to the connector 53, the vehicle-side connector 200 includes terminals and a connector case. Further, the vehicle-side connector 200 is provided with a harness 210 that is electrically connected to the terminals.

When the connector 53 and the vehicle-side connector 200 are attached, their terminals are electrically connected to each other. The electronic device 100 is electrically connected to an in-vehicle device via the vehicle-side connector 200 and the harness 210. The connector 53 corresponds to an external connection connector. The vehicle-side connector 200 corresponds to a mating connector.

### <Case>

As shown in FIGS. 1 and 2, the case 10 includes a base 20, a lid member 30, and a front cover 40. In FIG. 1, the first cover portion 41 of the front cover 40 and the lid member 30 are illustrated in a simplified manner. The base 20 and the lid member 30 correspond to a housing portion. That is, in the present embodiment, as an example, the housing portion including the base 20 and the lid member 30 is adopted.

As shown in FIG. 2, the base 20 has a bottom wall 21 and a side wall 22 continuous with the bottom wall 21. In addition, the bottom wall 21 is provided with a base 23 on which the circuit board 50 is mounted. The base 23 is also a portion to which the circuit board 50 is fixed. The base 23 is a member that protrudes from the surrounding area. The bases 23 are provided, for example, at four positions on the bottom wall 21. In FIG. 2 and other figures, in order to simplify the drawings, only a portion of the bases 23 is shown. It can also be said that the base 20 has three side walls 22.

The lid member 30 is disposed so as to face the surface of the wiring board 51. The lid member 30 is attached so as to sandwich a portion of the circuit board 50 between the lid member 30 and the base 20. The lid member 30 is fixed to the base 20 together with the circuit board 50 by means of screws, for example. The configuration and attaching structure of the lid member 30 are not particularly limited. For example, in a configuration in which the connector 53 is mounted on the back surface of the wiring board 51, the connector 53 is disposed between the wiring board 51 and the bottom wall 21. The lid member 30 may be in contact with the surface of the wiring board 51 in a ring shape so as to surround all of the circuit components 52.

Furthermore, the configuration of the housing portion is not limited to the above. In the present disclosure, the housing portion in which the base 20 and the lid member 30 are configured as a single unit may also be employed. In other words, the housing portion may have a configuration including a bottom wall 21, a side wall 22 connected to the bottom wall 21, and an upper wall connected to the side wall 22 and facing the bottom wall 21.

As shown in FIG. 2, the front cover 40 is disposed to face a first end surface OS1 of the base 20 and a second end surface OS2 of the lid member 30. The first end surface OS1 is an end surface of the bottom wall 21 and the side wall 22. In the present embodiment, as an example, the end surfaces OS1 and OS2 which are flat surfaces are used.

The front cover 40 is fixed to the base 20 by bolts 60. In other words, the front cover 40 is fixed to the base 20 by screws. It can also be said that the front cover 40 is fixed to the base 20 in the structure in which the base 20, the lid member 30, and the circuit board 50 are fixed.

The front cover 40 is provided with a screw hole 61 into which the bolt 60 is inserted. On the other hand, the base 20 is provided with a female thread that corresponds to the male thread of the bolt 60. The front cover 40 will be described in detail later.

As described above, the case 10 is formed by assembling the base 20, the lid member 30, and the front cover 40 together. Additionally, the case 10 defines an accommodation space 24 for the circuit board 50 by the base 20, the lid member 30 and the front cover 40. The base 20 and the lid member 30, together with the front cover 40, can be said to be members that form the accommodation space 24 for the circuit board 50. It can also be said that the front cover 40 together with the side wall 22 forms an annular wall of the case 10.

The front cover 40 corresponds to a cover. Hereinafter, when there is no need to distinguish between the base 20 and the lid member 30, they will also be referred to as a housing portion. The state in which the base 20, the lid member 30 and the front cover 40 are assembled is also simply referred to as an assembled state.

It can be said that the front cover 40 is fixed to the housing portion by means of screws. However, the front cover 40 may be fixed to the housing portion by a method other than screw fastening. For example, the front cover 40 and the housing portion may be fixed by a snap fit. In this case, the electronic device 100 does not need to use the bolts 60, and the number of parts can be reduced.

Furthermore, the front cover 40 may be fixed to the housing portion by heat staking or the like. Even in this case, the electronic device 100 does not need to use the bolts 60, and the number of parts can be reduced.

<Front cover>

The front cover 40 will now be described with reference to FIGS. 2 to 5. FIG. 4 shows the front cover 40 in a state where it is not assembled to the base 20 and the lid member 30.

As shown in FIG. 2, the front cover 40 includes two members: a first cover portion 41 and a second cover portion 42. The front cover 40 is also provided with an opening in which a connector 53 is disposed. In other words, the front cover 40 is provided with a through hole so that the connector 53 and the vehicle-side connector 200 can be connected. The opening can be referred to as a connector opening, a connector arrangement hole, a connector insertion hole, or the like.

In the present embodiment, as an example, the front cover 40 having two connector openings is used. However, it is sufficient that the front cover 40 is provided with at least one connector opening. Therefore, the front cover 40 may be provided with three or more connector openings.

As shown in FIG. 2 and other figures, the front cover 40 includes a first cover portion 41 and a second cover portion 42 in this order from the accommodation space 24 side. Therefore, the first cover portion 41 can be said to be one of the parts that form the accommodation space 24. On the other hand, the second cover portion 42 can be said to be one of the portions exposed to the outside of the case 10. More specifically, a first end EF1, which is an end of the second cover portion 42, forms part of the surface of the case 10.

First, the second cover portion 42 will be described. The second cover portion 42 is made of a hard material. The second cover portion 42 is made of, for example, a hard resin as a main component. The hard resin is polypropylene or the like. Incidentally, polypropylene is a hard resin of a propylene polymer. In other words, the second cover portion 42 is made of a general-purpose plastic. The second cover portion 42 is harder than the first cover portion 41. Further, the second cover portion 42 has electrical insulation properties. Therefore, the second cover portion 42 can be made lighter than one made mainly of metal.

However, the constituent material of the second cover portion 42 is not limited to those described above. The second cover portion 42 may be made of a hard material having electrical conductivity. For example, the second cover portion 42 may be made primarily of a metal such as aluminum, copper, or iron. In this case, the second cover portion 42 can have improved shielding properties against noise compared to a cover portion made mainly of hard resin. Furthermore, the second cover portion 42 can have improved rigidity compared to a cover portion made mainly of a hard resin.

As shown in FIGS. 2, 3 and 5, the second cover portion 42 is a rectangular member. The second cover portion 42 is provided with a second opening 42h which is a part of the connector opening. The second opening 42h is a through hole that opens in a thickness direction of the second cover portion 42. In the present embodiment, the second cover portion 42 is provided with two second openings 42h.

The second opening 42h has a larger opening area than that of the first opening 41h, which will be described later. In other words, the second opening 42h has a larger opening area than that of the first opening 41h in which the same connector 53 is disposed. In addition, in the second opening 42h and the first opening 41h which form one connector opening, the second opening 42h has a larger opening area than that of the first opening 41h. The second opening 42h and the first opening 41h forming one connector opening can be considered as a pair of openings.

Next, the first cover portion 41 will be described. The first cover portion 41 is made of a soft material. The first cover portion 41 is made of, for example, a soft resin as a main component. The soft resin is, for example, an elastomer. The elastomer is a soft resin having rubber elasticity. Therefore, the first cover portion 41 can elastically return to its original shape after being tensilely or compressively deformed. Moreover, the first cover portion 41 has electrical insulation properties.

However, the constituent material of the first cover portion 41 is not limited to those described above. The first cover portion 41 may be made of a soft material having electrical conductivity. Moreover, the first cover portion 41 may be made of soft resin mixed with a conductive filler. In this case, the first cover portion 41 can improve the shielding effect against noise compared to a cover having electrical insulation properties.

As shown in FIG. 2, the first cover portion 41 is a rectangular member. The first cover portion 41 is provided with a first opening 41h which is a part of the connector opening. The first opening 41h is a through hole that opens in the thickness direction of the first cover portion 41. In the present embodiment, the first cover portion 41 is provided with two first openings 41h.

As shown in FIGS. 2, 3, 4 and 5, the first cover portion 41 includes a base part 411, a protruding part 412 and a rib 413. The base part 411 is provided with a first opening 41h. Therefore, the first cover portion 41 includes a portion that forms the first opening 41h.

The portion that forms the first opening 41h is provided in an annular shape along the outer periphery of the connector 53. The portion forming the first opening 41h has at least a portion of the protruding part 412 that protrudes outside the accommodation space 24. The protruding part 412 is a portion for preventing foreign matter from entering the accommodation space 24.

The protruding part 412 is a portion that is connected to the base part 411 and is curved relative to the base part 411. Further, the protruding part 412 protrudes from the base part 411 toward the opposite side (outside) to the accommodation space 24.

As shown in FIG. 2, the protruding part 412 is provided so as to reach into the second opening 42h. In particular, it is preferable that the protruding part 412 be disposed closer to the accommodation space 24 than the second end EF2 of the vehicle-side connector 200. This makes it easier for the electronic device 100 to connect the vehicle-side connector 200 to the connector 53. Furthermore, the electronic device 100 can expand the range of applicability of the shape of the vehicle-side connector 200. The second end EF2 is an end of the vehicle-side connector 200 on the harness 210 side. The second end EF2 corresponds to the end on the harness side.

As shown in FIG. 2, the protruding part 412 are provided to face the side surfaces S1 to S4 of the connector 53. Furthermore, the protruding part 412 is provided so as to contact the side surfaces S 1 to S 4 of the connector 53. The protruding part 412 is made of a soft material. Therefore, the protruding part 412 can come into contact with the side surfaces S1 to S4 of the connector 53 with a relatively low load.

The protruding part 412 has the same thickness as the base part 411. However, the protruding part 412 may be thicker than the base part 411. This allows the electronic device 100 to further improve the effect of preventing the intrusion of foreign matter by the protruding part 412.

The area forming the first opening 41h includes a part of the base part 411 and the protruding part 412. However, the first cover portion 41 can also be considered to have the protruding part 412 as a portion that forms the first opening 41h.

As shown in FIG. 3, in the present embodiment, as an example, a protruding part 412 provided in an annular shape is adopted. In other words, the protruding part 412 is provided in an annular shape so as to surround the connector 53. However, the protruding part 412 may be provided corresponding to only a portion of the side surfaces of the outer periphery of the connector 53. For example, the protruding part 412 may be provided facing only one side surface. Furthermore, the protruding part 412 may be provided facing only three adjacent side surfaces, only two adjacent side surfaces, or only two opposing side surfaces. Furthermore, the protruding part 412 may be provided facing only a portion of at least one side surface of the connector 53. The protruding part 412 illustrated here is merely one example.

In the present embodiment, as an example, the protruding part 412 provided so as to contact the side surfaces S1 to S4 of the connector 53 is employed. However, the protruding part 412 does not have to be in contact with the side surfaces S1 to S4. Also, only a portion of the protruding part 412 may be in contact with the side surfaces S1 to S4.

In the present embodiment, as an example, a portion where the base part 411 and the protruding part 412 are connected is curved. However, the portion where the base part 411 and the protruding part 412 are joined may be at a right angle. In this case, the protruding part 412 can be said to be a thick portion of the base part 411 whose thickness is increased.

In the assembled state, a portion of the first cover portion 41 is disposed in contact with the second cover portion 42 and the housing portion. In other words, the first cover portion 41 includes a portion located between the first end surface OS1 of the base 20 and the second cover portion 42, and between the second end surface OS2 of the lid member 30 and the second cover portion 42. In addition, it can be said that a portion of the first cover portion 41 is provided between the lid member 30 and the second cover portion 42 or between the base 20 and the second cover portion 42. Therefore, the electronic device 100 can prevent foreign matter from entering the accommodation space 24 from the area where the first cover portion 41 is provided between the second cover portion 42 and the housing portion.

Moreover, the first cover portion 41 is made of a soft material. Therefore, the electronic device 100 can prevent the second cover portion 42 and the lid member 30 from interfering with each other and applying stress to each other. Similarly, the electronic device 100 can prevent the second cover portion 42 and the base 20 from interfering with each other and applying stress to each other.

Furthermore, the first cover portion 41 is sandwiched between the second cover portion 42 and the housing portion. That is, in the assembled state, the first cover portion 41 is pressed by the second cover portion 42 and the housing portion. This makes it possible for the electronic device 100 to prevent the first cover portion 41 and the second cover portion 42 from being separated from each other. It can also be said that the electronic device 100 can prevent the first cover portion 41 and the second cover portion 42 from peeling off from each other. Therefore, the durability of the front cover 40 of the electronic device 100 can be improved.

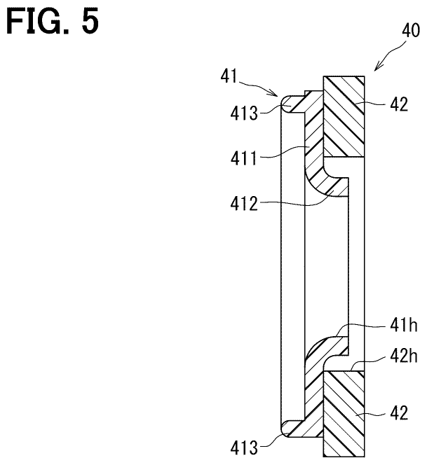

As shown in FIGS. 4 and 5, the rib 413 is a portion that protrudes from the surrounding area. The rib 413 protrudes toward the side of the accommodation space 24 with respect to the base part 411. Thus, the rib 413 protrudes on the opposite side from the protruding part 412. The rib 413 is provided in an annular shape. The rib 413 is located so as to face the first and second end surfaces OS1 and OS2.

The rib 413 is a portion that contacts a portion of the base 20 and lid member 30 in the assembled state. In other words, the rib 413 is in contact with the first and second end surfaces OS1 and OS2 in the assembled state. The rib 413 is pressed between the second cover portion 42, the base 20 and the lid member 30. As shown in FIG. 2, the rib 413 is then deformed by the pressing force. Therefore, the electronic device 100 can improve the adhesion between the front cover 40, the base 20, and the lid member 30. Thus, the electronic device 100 can further prevent foreign matter from entering between the front cover 40 and the housing portion.

In FIG. 2, the rib 413 is shown completely crushed. However, the rib 413 may remain in a protruding shape.

As shown in FIG. 2, the front cover 40 is provided with the first cover portion 41 and the second cover portion 42 in contact with each other. In detail, the first cover portion 41 and the second cover portion 42 are fixed and integrated. For example, the first cover portion 41 and the second cover portion 42 are fixed by crimping or gluing. Additionally, the first cover portion 41 and the second cover portion 42 are fixed together by outsert molding. Furthermore, when the second cover portion 42 is made mainly of a hard resin, the first cover portion 41 and the second cover portion 42 are fixed together by two-color molding.

In the present embodiment, the front cover 40 is used as an example of a cover with the first cover portion 41 and the second cover portion 42. However, the present disclosure is not only limited to the above example. The cover having the first cover portion 41 and the second cover portion 42 can be applied to any member that has an opening in the case 10 where the connector 53 is disposed.

### <Effect>

As described above, the electronic device 100 includes the front cover 40 having the first cover portion 41 made of a soft material and the second cover portion 42 made of a hard material. Therefore, the electronic device 100 can ensure strength. In other words, the electronic device 100 is more likely to meet the required strength against external stresses.

In addition, since a portion of the first cover portion 41 of the electronic device 100 is arranged along the outer periphery of the connector 53, the stress applied to the connector 53 can be reduced more than in a configuration in which a cover made of a hard material is arranged along the outer periphery of the connector 53.

Furthermore, the electronic device 100 has a configuration in which the portion forming the first opening 41h is annularly provided along the circumference of the connector 53. The portion forming the first opening 41h has at least a portion of the protruding part 412 that protrudes outside the accommodation space 24.

Therefore, the electronic device 100 can prevent the protruding part 412 from being peeled off even if a foreign matter attempts to enter the accommodation space 24. In other words, the protruding part 412 is not easily deformed toward the accommodation space 24 even if stress is applied from the outside in the direction of the accommodation space 24. Thus, the electronic device 100 can improve the effectiveness of inhibiting foreign matter from entering the accommodation space 24. In addition, the electronic device 100 will satisfy the IP40 requirements and will be more easily adaptable to the above rules.

The protruding part 412 and the side surfaces S1 to S4 are preferably made of a material that provides a coefficient of friction therebetween of 0.5 or more. According to this configuration, the protruding part 412 is unlikely to slip on the side surfaces S1 to S4 even if a foreign matter tries to enter the accommodation space 24 from the outside. In other words, the protruding part 412 can be further prevented from being peeled off even if stress is applied from the foreign matter. Thus, the electronic device 100 can further improve the effectiveness of inhibiting foreign matter from entering the accommodation space 24.

The preferred embodiments of the present disclosure have been described above. However, the present disclosure is not limited to the above embodiments at all, and various modifications can be made without departing from the gist of the present disclosure.

Hereinafter, as other embodiments of the present disclosure, second and third embodiments and first and second modified examples will be described. The above-described embodiment, the second and third embodiments, and the first and second modified examples can be implemented independently, or can be implemented in appropriate combination. The present disclosure is not limited to the combinations illustrated in the embodiments, and can be implemented by various combinations. In other embodiments, the same components as in the first embodiment are denoted by the same reference numerals as in the first embodiment.

### Second Embodiment

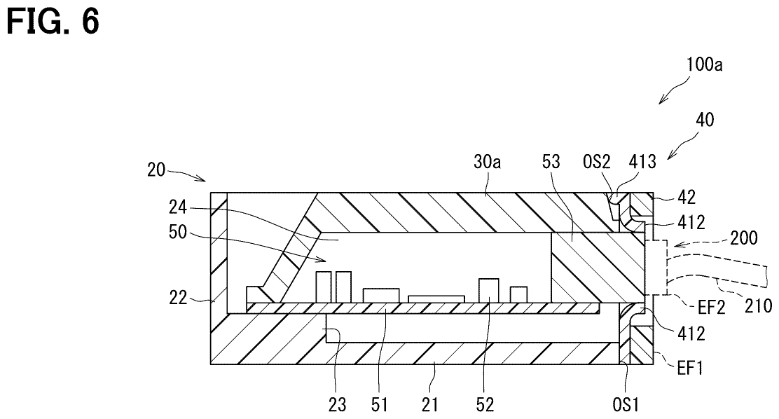

An electronic device 100a according to the second embodiment will be described with reference to FIG. 6. The same components as those in the first embodiment are denoted by the same reference numerals as those in the first embodiment. The electronic device 100a differs from the electronic device 100 in the configuration of the lid member 30a. The lid member 30a corresponds to a housing portion.

The lid member 30a includes an inclined surface on the second end surface OS2. The second end surface OS2 includes a portion that is inclined so that the distance between the second end surface OS2 and the second cover portion 42 becomes narrower as the second end surface OS2 approaches the accommodation space 24 from the outside. The inclined surface of the second end surface OS2 is in contact with the rib 413.

The electronic device 100a can have effects similar to the effects of the electronic device 100. Furthermore, in the electronic device 100a, the contact area between the lid member 30a and the first cover portion 41 can be increased. Therefore, the electronic device 100a can improve the effect of preventing foreign matter from entering between the lid member 30a and the front cover 40.

### Third Embodiment

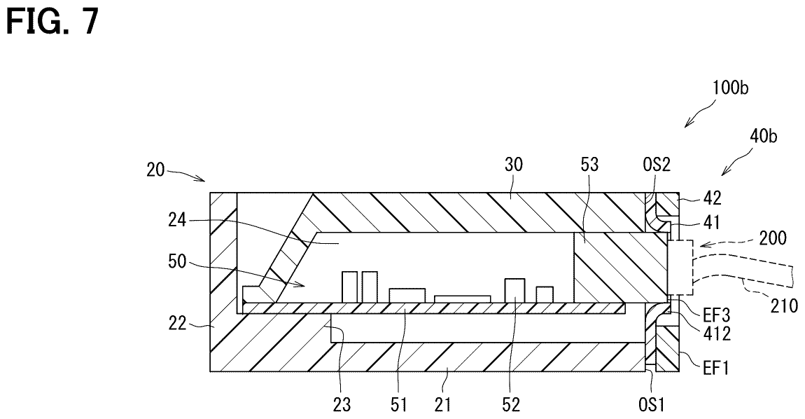

An electronic device 100b according to the third embodiment will be described with reference to FIG. 7. The electronic device 100a differs from the electronic device 100 in the configuration of the front cover 40b. The front cover 40b differs from the front cover 40 in the position of the protruding part 412. As in the first embodiment, the connector 53 is disposed from the accommodation space 24 to the outside of the accommodation space 24.

The protruding part 412 protrudes further away from the accommodation space 24 than the third end EF 3 of the connector 53. In other words, the protruding part 412 is provided so as to protrude toward the vehicle-side connector 200 side beyond the connector 53. The protruding part 412 is provided on at least a portion of the outer periphery of the connector 53 so as to protrude toward the vehicle-side connector 200. In other words, the third end EF3 of the connector 53 is located closer to the accommodation space 24 than the open end of the protruding part 412. The third end EF3 is an end portion of the connector 53 that is disposed outside the accommodation space 24. The third end EF3 corresponds to the outer end.

The electronic device 100a can have effects similar to the effects of the electronic device 100. Furthermore, the electronic device 100b can expand the range of applicability of the shape of the vehicle-side connector 200.

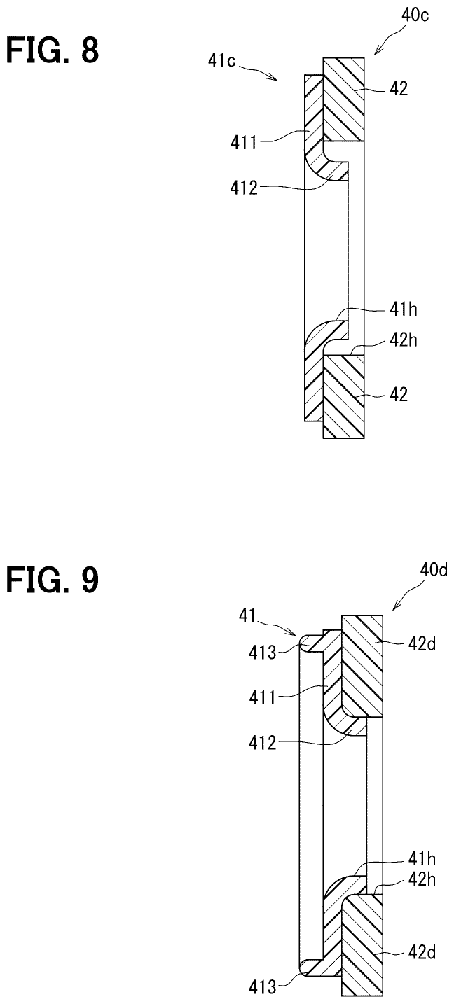

As shown in FIG. 8, a front cover 40c of the first modified example may include a first cover portion 41c in which the rib 413 is not provided. As shown in FIG. 9, in a front cover 40d of the second modified example, the second cover portion 42d may be in contact with the protruding part 412.

Although the present disclosure has been described in accordance with the embodiments, it is understood that the present disclosure is not limited to such embodiments or structures. The present disclosure encompasses various modifications and variations within the scope of equivalents. In addition, while various combinations and modes are described in the present disclosure, other combinations and modes including only one element, more elements, or less elements therein are also within the scope and spirit of the present disclosure.

What is claimed is:

1. An electronic device, comprising:
a circuit board equipped with an external connection connector; and
a case for accommodating the circuit board, wherein
the case includes
a cover having an opening in which the external connection connector is disposed, and
a housing portion that forms an accommodation space for the circuit board together with the cover,
the cover includes
a first cover portion made of a soft material and provided with a first opening which is a part of the opening, and
a second cover portion made of a hard material and in contact with the first cover portion, the second cover portion being a part of the opening and having a second opening having a larger opening area than the first opening, and
a portion forming the first opening is provided in an annular shape along an outer periphery of the external connection connector, and has at least a protruding part that protrudes outside the accommodation space.

2. The electronic device according to claim 1, wherein
a part of the first cover portion is disposed in contact with the second cover portion and the housing portion.

3. The electronic device according to claim 2, wherein
the first cover portion is sandwiched between the second cover portion and the
housing portion.

4. The electronic device according to claim 3, wherein
the first cover portion has a rib that protrudes from a surrounding area at a portion that contacts a part of the housing portion.

5. The electronic device according to claim 1, wherein
the second cover portion is made of a hard material having electrical conductivity.

6. The electronic device according to claim 1, wherein
the cover and the housing portion are fixed together by a snap fit.

7. The electronic device according to claim 1, wherein
the external connection connector is disposed from the accommodation space to the outside, and
the protruding part protrudes further away from the accommodation space than an outer end of a portion of the external connection connector disposed on the outside.

8. The electronic device according to claim 1, wherein
the external connection connector is connected to a mating connector having a harness, and
the protruding part is disposed closer to the accommodation space than a harness side end of the mating connector.

9. The electronic device according to claim 1, wherein
the first cover portion is made of a soft material having electrical conductivity.
